(19) United States
(12) Patent Application Publication
(10) Pub. No.: US 2025/0205751 A1
(43) Pub. Date: Jun. 26, 2025

(54) CLEANING BRUSH FOR SEMICONDUCTOR DEVICE AND CLEANING MODULE AND CMP EQUIPMENT AND POST-CMP CLEANING METHOD

(71) Applicant: SAMSUNG ELECTRONICS CO., LTD., Suwon-si (KR)

(72) Inventor: Gayoung Kim, Suwon-si (KR)

(21) Appl. No.: 18/792,279

(22) Filed: Aug. 1, 2024

(30) Foreign Application Priority Data
Dec. 20, 2023 (KR) 10-2023-0187541

(51) Int. Cl. B08B 1/34; H01L 21/02

(52) U.S. Cl. CPC B08B 1/34; H01L 21/02074

(57) ABSTRACT

The present disclosure relates to a cleaning brush for a semiconductor device, a cleaning module for a semiconductor device, a chemical mechanical polishing (CMP) equipment, and a post-CMP cleaning method. An example cleaning brush for a semiconductor device includes a polymer with a stimulus-responsive ligand. An example cleaning module for a semiconductor device includes the cleaning brush. An example chemical mechanical polishing equipment includes the cleaning module. An example post-CMP cleaning method uses the cleaning brush, the cleaning module, or the chemical mechanical polishing equipment.

### CROSS-REFERENCE TO RELATED APPLICATION

This application claims priority to and the benefit of Korean Patent Application No. 10-2023-0187541 filed in the Korean Intellectual Property Office on Dec. 20, 2023, the entire contents of which are incorporated herein by reference.

### BACKGROUND

Recently, according to the miniaturization of electronic devices and the subsequent scaling of integrated circuits, various methods of forming microstructures such as a metal wiring with a width of several nanometers or a narrow trench isolation have been studied.

In forming such microstructures, in order to create a flat surface of the microstructures, a polishing process such as a chemical mechanical polishing (CMP) may be performed. The CMP process may include providing polishing slurry including an abrasive between a semiconductor substrate and a polishing pad and then, contacting the semiconductor substrate with the polishing pad to planarize the surface of the substrate.

On the other hand, after the CMP process, a cleaning process may be performed by using a cleaning brush to physically remove polished particles such as polishing by-products.

### SUMMARY

Due to repeated use of the cleaning brush, contamination by polished particles may accumulate on the cleaning brush, which may adversely contaminate the semiconductor substrate during repeated cleaning steps and shorten the replacement cycle of the cleaning brush.

The present disclosure relates to a cleaning brush for a semiconductor device that may reduce or prevent reverse contamination of the semiconductor substrate in the cleaning step after the CMP process and increase the life-span of using it.

In some implementations, a cleaning module for a semiconductor device includes the cleaning brush for a semiconductor device.

In some implementations, CMP equipment includes the cleaning module for a semiconductor device.

In some implementations, a post-CMP cleaning method uses the cleaning brush for a semiconductor device, the cleaning module for a semiconductor device, or the chemical mechanical polishing equipment.

In some implementations, a cleaning brush for a semiconductor device includes a polymer with a stimulus-responsive ligand.

The stimulus-responsive ligand may include a functional group that accompanies a change in a chemical structure reversible by stimulation of external energy.

The change in the chemical structure of the functional group may change the binding force with a metal ion and the functional group may adsorb or desorb the metal ion depending on the stimulation of the external energy.

A change in the chemical structure of the functional group may include a change from cis-structure to trans-structure and from trans-structure to cis-structure.

A change in the chemical structure of the functional group may include a change from a non-ionic structure to a zwitterionic structure and a change from a zwitterionic structure to a non-ionic structure.

The stimulus-responsive ligand may form a coordination bond with a metal ion.

The external energy may include light, heat, electrical energy, or a combination thereof.

The functional group may include a spiropyranyl group, a spirooxaginyl group, an oxazyl group, an azobenzyl group, a boron-dipyromethenyl group, a derivative thereof, or a combination thereof.

The polymer may include a porous polymer, and the stimulus-responsive ligand may be on the side chain of the porous polymer.

The polymer may include polyvinyl alcohol with a spiropyranyl group, a spiroxazyl group, an oxazyl group, an azobenzyl group, a boron-dipyromethenyl group, a derivative thereof, or a combination thereof; polyurethane with a spiropyranyl group, a spiroxazyl group, an oxazyl group, an azobenzyl group, a boron-dipyromethenyl group, a derivative thereof, or a combination thereof; or a combination thereof.

In some implementations, a cleaning brush for a semiconductor device includes a porous polymer having a spiropyranyl group, a spiroxazyl group, an oxazyl group, an azobenzyl group, a boron-dipyromethenyl group, a derivative thereof, or a combination thereof.

The porous polymer may include polyvinyl alcohol, polyurethane, or a combination thereof.

In some implementations, a cleaning module for a semiconductor device includes the cleaning brush, and an energy source configured to supply heat, light, or electrical energy to the cleaning brush.

The cleaning module may further include a first nozzle configured to supply a first cleaning liquid for removing CMP polished particles.

The cleaning module may further include a second nozzle configured to supply a second cleaning liquid for removing the polished particles chemically desorbed from the cleaning brush.

The first nozzle or the second nozzle may be disposed in an interior space of the cleaning brush or may be disposed outside the cleaning brush.

In some implementations, a CMP equipment includes a CMP module and the cleaning module for a semiconductor device is provided.

In some implementations, a post-CMP cleaning method includes supplying a first cleaning liquid to a polished surface where the CMP has been performed and contacting the polished surface with the cleaning brush to remove polished particles from the polished surface, separating the cleaning brush from the polished surface, and supplying external energy to the cleaning brush to chemically desorb the polished particles chemically adsorbed on the cleaning brush.

The method may further include supplying a second cleaning liquid to the cleaning brush to physically separate the polished particles that are chemically desorbed from the cleaning brush from the cleaning brush.

The external energy may be selected from light, heat, electric energy, or a combination thereof.

According to some example implementations, reverse contamination of the semiconductor substrate may be effectively reduced or prevented in the cleaning step after the CMP process and the life-span of use of the cleaning brush may be increased.

### BRIEF DESCRIPTION OF THE DRAWINGS

FIG. 1 is a schematic view showing an example of a cleaning brush for a semiconductor device.

FIG. 2 is an example cross-sectional view of the cleaning brush for the semiconductor device of FIG. 1.

FIG. 3 is a schematic view showing an example of a cleaning module for a semiconductor device.

FIG. 4 is a schematic view showing an example of a CMP equipment.

FIG. 5 is a schematic view showing an example of a CMP module included in a CMP equipment.

### DETAILED DESCRIPTION

The present disclosure will be described more fully hereinafter with reference to the accompanying drawings, in which implementations of the present disclosure are shown. As those skilled in the art would realize, the described implementations may be modified in various different ways, all without departing from the spirit or scope of the present disclosure.

To clearly describe the present disclosure, parts that are irrelevant to the description are omitted, and like numerals refer to like or similar constituent elements throughout the specification.

The size and thickness of each constituent element as shown in the drawings are randomly indicated for better understanding and ease of description, and this disclosure is not necessarily limited to as shown. In the drawings, the thickness of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise,” and variations such as “comprises” or “comprising,” will be understood to imply the inclusion of stated elements but not the exclusion of any other elements.

Further, throughout the specification, the phrase “a plan view” means when an object portion is viewed from above, and the phrase “a cross-sectional view” means when a cross-section taken by vertically cutting an object portion is viewed from the side.

Additionally, throughout the specification, “substrate,” “semiconductor substrate,” “wafer” or “semiconductor wafer” may include a pure semiconductor substrate, a semiconductor substrate with an epitaxial layer, a semiconductor substrate including one or more conductive layers, an insulating layer and/or a semiconductor layer, another type of substrate including one or more semiconductor layers, or a combination thereof. Hereinafter, a cleaning brush for semiconductor devices according to some implementations will be described.

A cleaning brush for a semiconductor device (hereinafter referred to as a ‘cleaning brush’) may be a tool used for cleaning in the manufacturing process of a semiconductor device, and may include any tool, regardless of shape or size, that contact a surface (e.g., the surface of a semiconductor substrate) and perform a physical action such as scrubbing. As an example, the cleaning brush may be a post-CMP cleaning brush used in a cleaning step after a chemical mechanical polishing (CMP) process.

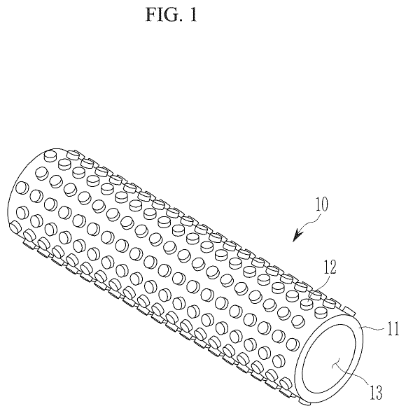

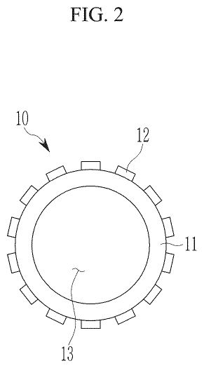

FIG. 1 is a schematic view showing an example of a cleaning brush for a semiconductor device, and FIG. 2 is an example cross-sectional view of the cleaning brush for the semiconductor device of FIG. 1.

Referring to FIGS. 1 and 2, the cleaning brush 10 may have a cylindrical main body 11 that may rotate in a predetermined direction, and a plurality of protrusions 12. The cylindrical main body 11 may be fitted by being inserted at a predetermined rotation axis and while rotating in one direction such as clockwise or counterclockwise, contact the surface of an object to be cleaned (e.g., a semiconductor substrate). The plurality of protrusions 12 may increase friction between the cleaning brush 10 and the object to be cleaned when the cleaning brush 10 rotates to effectively separate contaminated particles (e.g., polished particles after CMP) from the object to be cleaned. However, the plurality of protrusions 12 may be omitted.

The cleaning brush 10 may have an interior space 13, into which the rotation axis may be inserted or which may be equipped with a first nozzle 112 and/or a second nozzle 132 configured to supply a cleaning liquid and/or water.

The cleaning brush 10 may include a polymer, for example, a porous polymer which may well absorb or discharge liquids such as the water or the cleaning liquid without damaging on the surface of the object to be cleaned (e.g., the surface of a semiconductor substrate). The porous polymer may include, for example, a polyvinyl alcohol (PVA)-based polymer, a polyurethane (PU)-based polymer, or a combination thereof, but is not limited thereto.

The polymer may include, for example, a main chain including repeating units derived from vinyl alcohol, urethane, or a combination thereof, and a ligand bound to the main chain in at least a portion of the repeating units. The ligand may be included in a side chain of the polymer and include a functional group capable of forming a coordination bond with metal ions. For example, the ligand may form a complex compound by having the coordination bond with metal ions in the polished particles polished by CMP in the cleaning step after CMP and thereby, effectively adsorb the polished particles including the metal ions.

As an example, the ligand may include a stimulus-responsive ligand. The stimulus-responsive ligand may include a functional group configured to reversibly change a chemical structure on stimulation of external energy, for example, vary a binding force with metal ions depending on the stimulation of external energy (i.e., presence or absence of the stimulation of external energy or types of the external energy) and accordingly, adsorb or desorb the metal ions depending on the stimulation of external energy. Herein, the external energy may include light, heat, electrical energy, or a combination thereof.

The stimulus-responsive ligand may be structurally changed in response to the external energy. For example, whereas the complex compound formed by a coordination bond of the ligand with the metal ions may have a relatively high bonding force between the ligand of the polymer of the cleaning brush 10 and the metal ions, the bonding force of the ligand with the metal ions may be weakened by supplying the external energy such as light, heat, electric energy, or a combination thereof, which structurally changes the functional group of the ligand. Such a bonding force difference of the functional group of the ligand with the metal ions may cause the metal ions to be chemically adsorbed or desorbed onto the polymer of the cleaning brush 10, which may control discharge of the metal ions.

For example, in the cleaning step, the stimulus-responsive ligand of the polymer of the cleaning brush 10 may form a complex compound through a coordination bond with metal ions to chemically adsorb the metal ions, and then after the cleaning step, the stimulus-responsive ligand may have a structural change that the coordination bond with the metal ions is weakened (e.g., structurally released) by stimulation of external energy, thereby chemically desorbing the metal ions.

For example, the chemical structure change by the stimulation of external energy may include a change from a cis-structure to a trans-structure and a reversible change from the trans-structure to the cis-structure. One of these two structures may be a structure configured to chemically adsorb metal ions by forming a complex compound with the metal ions, and the other of these two may be a structure configured to chemically desorb the metal ions by breaking the bond with the metal ions. For example, as shown below, a functional group with the trans-structure may be changed into a functional group with the cis-structure by irradiating UV light, and then the functional group with the cis-structure may form a complex compound with metal ions (M+), and in addition, by irradiating visible light (Vis), the functional group with the cis-structure may be reversibly changed to the functional group with the trans-structure, but the present disclosure is not limited thereto.

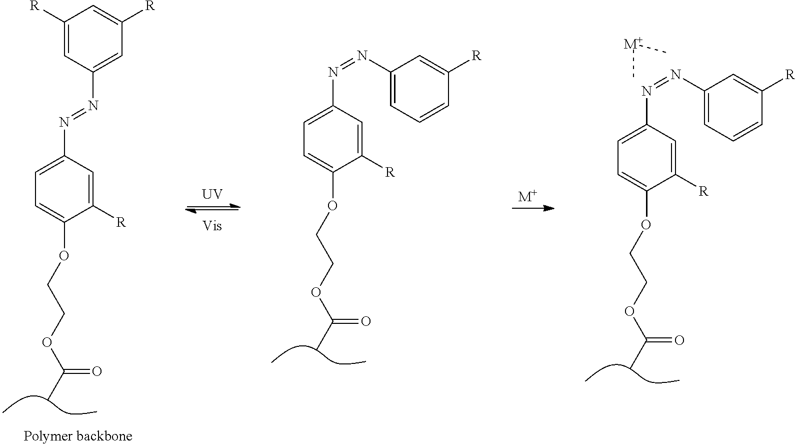

For example, a change in chemical structure due to stimulation of external energy may include a change from a non-ionic structure to a zwitterion structure and a change from a zwitterionic structure to a non-ionic structure. The zwitterionic structure may be a structure configured to chemically adsorb metal ions, and the non-ionic structure may be a structure configured to chemically desorb the metal ions by releasing a bond with the metal ions. For example, as shown below, a non-ionic functional group may be changed into a zwitterion functional group by irradiating UV light, and then the zwitterion functional group may form a complex compound with metal ions (M²⁺), and in addition, by irradiating visible light (Vis), the zwitterion functional group may be changed to the non-ionic functional group, but is not limited thereto.

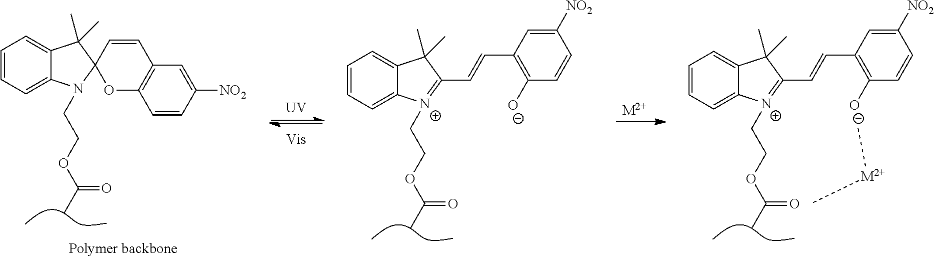

Such a functional group may be, for example, a responsive functional group capable of donating one or more electron pairs to a metallic material and simultaneously responding sensitively to external energy such as light, heat, electrical energy, or a combination thereof, and may include, for example, an amide group, an amino group, an imine group, a disulfide group, a carbonyl group, a carboxylic group, a derivative thereof, or a combination thereof, bonded to a responsive functional group, for example a spiropyranyl group, a spiroxazinyl group, an oxazinyl group, an azobenzyl group, and a boron-dipyrromethenyl group. group, a derivative thereof, or a combination thereof, but is not limited thereto.

In this way, the cleaning brush 10 may have a ligand configured to form a coordination bond with metal ions in a side chain of a polymer to form a complex compound with the metal ions in the polished particles in the cleaning step, and thus chemically adsorb the metal ions, wherein because the ligand may have a functional group configured to reversibly change its chemical structure by stimulation of external energy, the metal ions that are chemically adsorbed (e.g., coordination bond) on the cleaning brush 10 may be chemically desorbed by supplying external energy such as light, heat, and/or electrical energy to the cleaning brush 10 after the cleaning step, thereby effectively desorbing the polished particles from the cleaning brush 10. This adsorption and desorption of the metal ions may reversibly occur depending on presence or absence of the external energy or types of the external energy.

For example, when the external energy is light, the light may be UV light, visible light, infrared light, or a combination thereof. Irradiation of light may be performed, for example, at an intensity of about 1 to 10 mW/cm² (based on a wavelength of about 300 nm to about 400 nm) for about 5 to about 20 minutes, but is not limited thereto.

For example, when the external energy is heat, for example, heat treatment may be required at a temperature of about 50° C. or higher, and within the above range, heat treatment may be needed at a temperature of about 50 to about 90° C. for about 10 to about 90 minutes.

In this way, the cleaning brush 10 may chemically adsorb and desorb metal ions, thereby increasing the cleaning efficiency of polished particles including metal ions, and at the same time, the polished particles collected in the cleaning brush 10 may be removed by itself. In addition, this may effectively reduce or prevent the accumulation of contamination due to repeated use of the cleaning brush 10, and prevent reverse contamination of the object to be cleaned (e.g., semiconductor substrate) during repeated cleaning steps, thereby increasing a yield of the semiconductor process.

In some implementations, the cylindrical cleaning brush 10 is described as an example, but the present disclosure is not limited thereto, and may be equally applied to a flat cleaning brush, a rod-shaped cleaning brush, or a pencil-shaped cleaning brush.

Hereinafter, a cleaning module for a semiconductor device including the aforementioned cleaning brush 10 will be described.

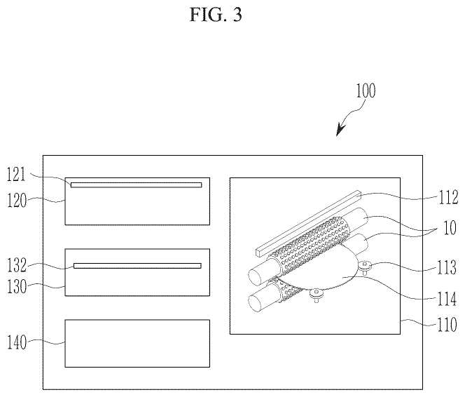

FIG. 3 is a schematic view showing an example of a cleaning module for a semiconductor device.

Referring to FIG. 3, the cleaning module 100 for a semiconductor device includes a cleaning section 110 for cleaning the object to be cleaned, an energy supply section 120 for applying external energy to the used cleaning brush 10, a rinse section 130 for physically removing polished particles from the cleaning brush 10, and a drying section 140.

The cleaning section 110, which is an area where an object to be cleaned is cleaned by using the cleaning brush 10, includes the cleaning brush 10; fixing unit 113 configured to support and fix the object to be cleaned 114 (e.g., a semiconductor substrate as a wafer); and a first nozzle 112 configured to supply a cleaning liquid.

The cleaning brush 10 is the same as described above and may be positioned on and/or under one surface or both surfaces of the object to be cleaned 114 to clean one surface or both surfaces of the object to be cleaned 114. The cleaning brush 10 may be fitted with a rotation axis inserted therein and while rotating in an opposite direction to that of the object to be cleaned 114, may contact the surface of the object to be cleaned 114 to remove polished particles (e.g., metal particle) thereon.

The fixing unit 113 may fix and rotate the object to be cleaned 114 and for example include, a groove into which the object to be cleaned 114 may be inserted and a rotation axis rotating in one direction. There may be a plurality of the fixing unit 113, which may be arranged at predetermined intervals.

The first nozzle 112 may provide a cleaning liquid and/or water to the object to be cleaned 114. The first nozzle 112 may be located in an inner space of the cleaning brush 10 or mounted on the inner space of the cleaning brush 10 or located outside the cleaning brush 10 and for example, may have a shape extending in one direction, but is not limited thereto.

The first nozzle 112 may spray the cleaning liquid and/or water toward the cleaning brush 10, wherein the cleaning liquid and/or water may be supplied at an appropriate pressure to effectively remove the polished particles. The cleaning section 110 may further include a voltage supply unit configured to apply a predetermined voltage to the first nozzle 112, and the voltage applied from the voltage supply unit may charge the cleaning liquid and/or water in the first nozzle 112 and then, discharge it toward the object to be cleaned 114. The cleaning liquid sprayed from the first nozzle 112 may include a metal chelate component to effectively remove the polished particles, for example, including metal ions.

The energy supply section 120, the rinse section 130, and the drying section 140 are zones that self-clean and dry the cleaning brush 10 used in the cleaning section 110. The energy supply section 120 includes an energy source 121 configured to supply heat, light, or electrical energy to the cleaning brush 10. The energy source 121 may have a long-shape in one direction so as to supply heat, light, or electrical energy to the cleaning brush 10, but is not limited thereto. The energy source 121 may be, for example, a heater, a lamp, an electric device, or a combination thereof, but is not limited thereto.

As described above, the cleaning brush 10 used in the cleaning section 110 may have the polished particles chemically adsorbed thereon, wherein the cleaning brush 10 on which the polished particles are chemically adsorbed may be supplied with heat, light, and/or electrical energy from the energy source 121 to chemically desorb the polished particles due to chemical structure changes of the stimulus-responsive ligand of the cleaning brush 10, as described above.

The rinse section 130 may physically desorb the polished particles chemically desorbed from the cleaning brush 10 in the energy supply section 120. The rinse section 130 includes a second nozzle 132. The second nozzle 132 may supply the cleaning liquid and/or water to physically remove the polished particles chemically desorbed from the cleaning brush 10. The second nozzle 132 may be positioned in an inner space of the cleaning brush 10 or mounted on the cleaning brush 10 or located outside the cleaning brush 10 and for example, may have a long shape of extending in one direction, but is not limited thereto. The second nozzle 132 may spray the cleaning liquid and/or water toward the cleaning brush 10, wherein the cleaning liquid and/or water may be supplied at an appropriate pressure to effectively remove the polished particles desorbed from the cleaning brush 10.

The rinse section 130 may further include a voltage supply unit configured to apply a predetermined voltage to the second nozzle 132, and the voltage applied from the voltage supply unit may charge the cleaning liquid and/or water in the second nozzle 132 and discharge the cleaning liquid and/or water toward the cleaning brush 10.

The drying section 140 is a section for drying the cleaning brush 10 self-cleaned in the energy supply section 120 and the rinse section 130. The drying section 140 may dry the cleaning brush 10, for example, with blowing air, and the like.

The cleaning brush 10 dried in the drying section 140 may be used again to clean the object to be cleaned 114 in the cleaning section 110, and as described above, the cleaning brush 10 with little or no contamination may be obtained through a process of independently removing the polished particles adsorbed on the cleaning brush 10.

Hereinafter, an example of a cleaning method after CMP (post CMP) using the aforementioned cleaning module 100 for a semiconductor device will be described with reference to FIG. 3.

First, the object to be cleaned 114 is fixed using the fixing unit 113 in the cleaning section 110. Next, the cleaning brush 10 is placed on both surfaces of the object to be cleaned 114 (for example, the polished surface on which CMP is performed), and the cleaning liquid is supplied through the first nozzle 112. Subsequently (or simultaneously with supplying the cleaning liquid), the cleaning brush 10 is brought into contact with the surface of the object to be cleaned 114 to remove polished particles from the object to be cleaned 114. At least some of the polished particles may be chemically adsorbed to the cleaning brush 10.

Next, when cleaning is completed, the cleaning brush 10 is separated from the object to be cleaned 114.

Next, the cleaned cleaning brush 10 is moved to the energy supply section 120 and light, heat, and/or electric energy is supplied from the energy source 121 to chemically desorb polished particles chemically adsorbed on the cleaning brush 10.

Next, the cleaning brush 10 is moved to the rinse section 130 and the cleaning liquid and/or water is supplied to the cleaning brush 10 from the second nozzle 132. The cleaning liquid and/or water supplied from the second nozzle 132 may physically separate the chemically desorbed polished particles from the cleaning brush 10.

Next, the cleaning brush 10 is moved to the drying section 140 and the moisture remaining on the cleaning brush 10 is dried.

Next, the dried cleaning brush 10 may be moved back to the cleaning section 110 and the cleaning steps described above may be repeated.

Hereinafter, a CMP equipment including the aforementioned cleaning module 100 for a semiconductor device will be described.

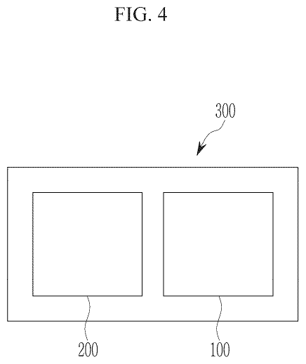

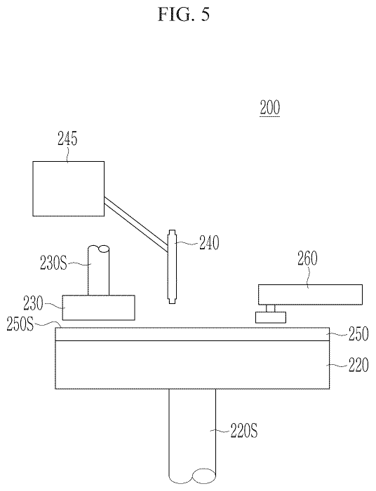

FIG. 4 is a schematic view showing an example of a CMP equipment, and FIG. 5 is a schematic view showing an example of a CMP module included in a CMP equipment.

Referring to FIG. 4, a CMP equipment 300 for a semiconductor device includes a cleaning module 100 and a CMP module 200.

The cleaning module 100 for a semiconductor device is the same as described above.

Referring to FIG. 5, the CMP module 200 includes a platen 220; a polishing head 230; a polishing slurry supplier 240; a polishing pad 250; and a pad conditioner 260.

The platen 220 may be rotatably provided on the surface of the lower base. The platen 220 may receive rotational power from a motor disposed in the lower base, and thus the platen 220 may rotate in a certain direction, such as clockwise or counterclockwise, by the rotation axis 220S perpendicular to the surface.

The polishing head 230 may be disposed on top of the platen 220 to support the object to be polished. The object to be polished may be, for example, a semiconductor substrate such as a wafer. The polishing head 230 may include a rotation axis 230S rotating the object to be polished. When the polishing is performed, the polishing head 230 may have an opposite rotation direction to that of the platen 220.

The polishing slurry supplier 240 may receive polishing slurry from the polishing slurry tank 245 and discharge it onto the polishing pad 250 to be described later. The polishing slurry supplier 240 may include a nozzle capable of supplying the polishing slurry onto the polishing pad 250 during the polishing process and a voltage supply unit capable of applying a predetermined voltage to the nozzle. The polishing slurry in the nozzle may be charged by the voltage applied from the voltage supply unit and then, discharged toward the polishing pad 250.

The polishing pad 250 may be positioned on top of the platen 220 to be supported by the platen 220. The polishing pad 250 may rotate together with the platen 220.

The polishing pad 250 may include a polishing surface 250S positioned to face the object to be polished, which is fixed to the polishing head 230, that is, a semiconductor substrate such as a wafer. When the polishing is performed, the polishing surface 250S of the polishing pad 250 is in direct contact with the object to be polished, of which the surface may be chemically and/or mechanically polished by using nano-sized polishing particles in the polishing slurry. Herein, the polishing surface 250S of the polishing pad 250 may have a surface in direct contact with the object to be polished and a predetermined depth therefrom, wherein the predetermined depth may be about 10% to about 100%, about 20% to about 100%, about 30% to about 100%, about 40% to about 100%, or about 50% to about 100% of a thickness of the polishing pad 250.

The pad conditioner 260 may be disposed adjacent to the polishing pad 250, and the polishing surface 250S of the polishing pad 250 may maintain predetermined surface roughness to effectively polish the object to be polished during the polishing process. For example, the pad conditioner 260 may polish the polishing surface 250S of the polishing pad 250 in a state of stopping the polishing to restore or maintain surface roughness of the polishing surface 250S of the polishing pad 250. The pad conditioner 260 may rotate in a predetermined direction such as clockwise or counterclockwise along a predetermined rotation axis.

The chemical mechanical polishing device 200 may further include a surface roughness measuring device capable of measuring the surface roughness of the polishing surface 250S of the polishing pad 250. The surface roughness measuring device may achieve constant polishing performance by precisely measuring the surface roughness of the polishing surface 250S of the polishing pad 250 in real time.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with some implementations, it is to be understood that the present disclosure is not limited to the disclosed implementations, but, on the contrary, is intended to cover various modifications and equivalent arrangements included within the spirit and scope of the appended claims.

What is claimed is:

1. A cleaning brush for a semiconductor device, the cleaning brush comprising:
a polymer with a stimulus-responsive ligand.

2. The cleaning brush of claim 1, wherein the stimulus-responsive ligand comprises a functional group that accompanies a change in a chemical structure, the chemical structure being reversible based on stimulation of external energy.

3. The cleaning brush of claim 2, wherein
a binding force between the stimulus-responsive ligand and a metal ion is configured to vary based on the change in the chemical structure of the functional group, and
the functional group is configured to adsorb or desorb the metal ion based on the stimulation of the external energy.

4. The cleaning brush of claim 2, wherein the change in the chemical structure of the functional group comprises a change from cis-structure to trans-structure and a change from the trans-structure to the cis-structure.

5. The cleaning brush of claim 2, wherein the change in the chemical structure of the functional group comprises a change from a non-ionic structure to a zwitterionic structure and a change from the zwitterionic structure to the non-ionic structure.

6. The cleaning brush of claim 2, wherein the stimulus-responsive ligand is configured to form a coordination bond with a metal ion.

7. The cleaning brush of claim 2, wherein the external energy comprises light, heat, electrical energy, or a combination thereof.

8. The cleaning brush of claim 2, wherein the functional group comprises a spiropyranyl group, a spirooxaginyl group, an oxazyl group, an azobenzyl group, a boron-dipyromethenyl group, a derivative thereof, or a combination thereof.

9. The cleaning brush of claim 1, wherein
the polymer comprises a porous polymer, and
the stimulus-responsive ligand is on a side chain of the porous polymer.

10. The cleaning brush of claim 1, wherein the polymer comprises
polyvinyl alcohol with a spiropyranyl group, a spiroxazyl group, an oxazyl group, an azobenzyl group, a boron-dipyromethenyl group, a derivative thereof, or a combination thereof;
polyurethane with a spiropyranyl group, a spiroxazyl group, an oxazyl group, an azobenzyl group, a boron-dipyromethenyl group, a derivative thereof, or a combination thereof; or
a combination thereof.

11. A cleaning brush for a semiconductor device, the cleaning brush comprising:
a porous polymer having a spiropyranyl group, a spiroxazyl group, an oxazyl group, an azobenzyl group, a boron-dipyromethenyl group, a derivative thereof, or a combination thereof.

12. The cleaning brush of claim 11, wherein the porous polymer comprises polyvinyl alcohol, polyurethane, or a combination thereof.

13. The cleaning brush of claim 1, wherein heat, light, or electrical energy is supplied to the cleaning brush by energy source.

14. The cleaning brush of claim 13, wherein a first cleaning liquid configured to remove polished particles is supplied by a first nozzle.

15. The cleaning brush of claim 14, wherein a second cleaning liquid configured to remove the polished particles chemically desorbed from the cleaning brush is supplied by a second nozzle.

16. The cleaning brush of claim 15, wherein the first nozzle or the second nozzle is disposed inside the cleaning brush or is disposed outside the cleaning brush.

17. The cleaning brush of claim 13, wherein the cleaning brush is comprised in a chemical mechanical polishing (CMP) equipment, and the CMP equipment comprises a CMP module.

18. A post chemical mechanical polishing (post-CMP) cleaning method, comprising:
supplying a first cleaning liquid to a polished surface where a CMP has been performed,
contacting the polished surface with the cleaning brush for a semiconductor device of claim 1 that removes polished particles from the polished surface,
separating the cleaning brush from the polished surface, and
supplying external energy to the cleaning brush to cause the cleaning brush to chemically desorb the polished particles, the polished particles being chemically adsorbed on the cleaning brush.

19. The method of claim 18, comprising supplying a second cleaning liquid to the cleaning brush to physically separate the polished particles from the cleaning brush, the polished particles being chemically desorbed on the cleaning brush.

20. The method of claim 18, wherein the external energy is selected from light, heat, electric energy, or a combination thereof.
